(19) United States
(12) Patent Application Publication
(10) Pub. No.: US 2012/0097228 A1
(43) Pub. Date: Apr. 26, 2012

(54) SOLAR CELL

(75) Inventors: Hirofumi Yoshikawa, Osaka-shi (JP); Tomohiro Nozawa, Osaka-shi (JP); Makoto Izumi, Osaka-shi (JP); Yasutaka Kuzumoto, Osaka-shi (JP)

(73) Assignee: SHARP KABUSHIKI KAISHAO, Osaka-shi (JP)

(21) Appl. No.: 13/270,853

(22) Filed: Oct. 11, 2011

(30) Foreign Application Priority Data
Oct. 21, 2010 (JP) 2010-236723

(51) Int. Cl. H01L 31/06

(52) U.S. Cl. 136/255

(57) ABSTRACT

A solar cell of the present invention comprises a p-type semiconductor layer, an n-type semiconductor layer, and a superlattice semiconductor layer interposed between the p-type semiconductor layer and the n-type semiconductor layer, wherein the superlattice semiconductor layer has a superlattice structure in which barrier layers and quantum dot layers comprising quantum dots are stacked alternately and repeatedly, and is formed so that the bandgaps of the quantum dots are gradually widened with increasing distance from a side of the p-type semiconductor layer and decreasing distance to a side of the n-type semiconductor layer.

### CROSS-REFERENCE TO RELATED APPLICATION

This application is related to Japanese Patent Application No. 2010-236723 filed on Oct. 21, 2010, whose priority is claimed under 35 USC §119, and the disclosure of which is incorporated by reference in its entirety.

### BACKGROUND OF THE INVENTION

1. Field of the Invention

The present invention relates to a solar cell having a superlattice structure.

2. Description of the Related Art

Research and development on solar cells has been carried out in various directions in order to utilize light in a wider wavelength range and enhance photoelectric conversion efficiency. For example, there has been proposed a solar cell that can utilize light of a longer wavelength by exciting electrons in two steps with an intermediate band provided between a valence band and a conduction band by a quantum dot technique (for example, Physical Review Letters, vol. 97, 2006, page 247701).

Such a solar cell having quantum dots is obtained by inserting a superlattice semiconductor layer including quantum dot layers having quantum dots as an i-type semiconductor layer into a compound-semiconductor solar cell. In the superlattice semiconductor layer inserted in matrix semiconductors, the quantum dots are electronically coupled to form a superlattice miniband. The two-step optical excitation through the miniband allows absorption of light of a wavelength range that has not been utilized (absorption of photons having energy smaller than the bandgap of the matrix materials) to increase photocurrent. Carriers generated in the quantum dots move through the miniband and are transferred to the p-type and n-type matrix semiconductor regions by optical excitation or thermal excitation.

In the meantime, in the field of quantum-cascade lasers, there has been proposed a superlattice structure in which a miniband is formed in the presence of a voltage applied (for example, Japanese Unexamined Patent Publication No. 2000-101201).

In order to enhance the conversion efficiency of a quantum dot solar cell having a p-i-n layered structure utilizing a miniband, it is necessary to enhance the efficiency of carrier extraction from an i-type semiconductor layer to p-type and n-type semiconductor layers while forming a miniband in the i-type semiconductor layer in the presence of an internal electric field. In an existing quantum dot solar cell utilizing a miniband, the photocurrent extraction efficiency in the quantum dots is not more than several % at maximum. This is considered due to the following problems in optical excitation and thermal excitation by which carriers are extracted from the quantum dots. In the optical excitation through the miniband, the generation rate of the second photon is slower than the recombination rate in the quantum dots. In the thermal excitation, the energy barrier is so larger than the thermal energy kT (k: Boltzmann constant, T: absolute temperature) for the carriers generated in the quantum dots as to discourage carrier excitation (thermal energy at 300 K of room temperature is approximately 26 meV). It is therefore an object how to efficiently extract carriers from the quantum dot layers to the p-type and n-type semiconductor regions.

In addition, when an electric field is applied, resonant tunneling effect between quantum levels for forming a miniband structure is broken to cause wave function localization, which is a phenomenon called Wannier-Stark localization. In terms of energy, the quantum levels are split into Stark-ladder states with the energy spacing of eFD (D: superlattice period, F: electric field strength) to affect the miniband formation. When a miniband cannot be formed, carriers generated in each quantum dot need to climb over a barrier layer to move to an adjacent quantum dot, and the efficiency of carrier extraction is therefore significantly reduced.

In the field of quantum-cascade lasers, there is a case in which the Stark effect is taken into account (Japanese Unexamined Patent Publication No. 2000-101201), but there are no conventional quantum dot solar cell models in which the Stark effect is taken into account. In the structure disclosed in Japanese Unexamined Patent Publication No. 2000-101201, a plurality of flat-band minibands are formed by varying the thicknesses of quantum well layers or barrier layers. In the structure, electrons injected radiatively transit from an upper miniband to a lower miniband, move from the lower miniband to an upper miniband in an adjacent unit through an injection/relaxation region, and radiatively transit again to an lower miniband, and the series of actions is repeated. In the field of solar cells, on the other hand, carrier transfer in an absorber layer, which is an i-type semiconductor layer, needs to be efficient, and it is therefore desirable to form one miniband across the i-type semiconductor layer. In the structure disclosed in Japanese Unexamined Patent Publication No. 2000-101201, a plurality of flat-band minibands are formed throughout the superlattice structure, but none of the minibands runs from one end to the other end of the superlattice structure. In addition, quantum levels of quantum wells having discrete energy values can be varied due to a slight difference in thickness, it is complicating in manufacturing process to form a superlattice structure so that both the minibands are flat-band in consideration of the Stark effect.

### SUMMARY OF THE INVENTION

In view of the above-described circumstances, the present invention has been achieved to provide a solar cell having a superlattice structure in which a miniband is formed, and carriers are efficiently extracted to p-type and n-type semiconductor regions.

The present invention provides a solar cell comprising a p-type semiconductor layer, an n-type semiconductor layer, and a superlattice semiconductor layer interposed between the p-type semiconductor layer and the n-type semiconductor layer, wherein the superlattice semiconductor layer has a superlattice structure in which barrier layers and quantum dot layers comprising quantum dots are stacked alternately and repeatedly, and the superlattice semiconductor layer is formed so that the bandgaps of the quantum dots are gradually widened with increasing distance from a side of the p-type semiconductor layer and decreasing distance to a side of the n-type semiconductor layer.

According to the present invention, the superlattice semiconductor layer has a superlattice structure in which barrier layers and quantum dot layers comprising quantum dots are stacked alternately and repeatedly, and it is therefore possible to form a miniband in the superlattice structure so that electronic transition through the miniband can be used in addition to normal valence band-to-conduction band transition to allow utilization of light in a wider wavelength range and enhance the photoelectric conversion efficiency.

According to the present invention, the superlattice semiconductor layer is formed so that the bandgaps of the quantum dots are gradually widened with increasing distance from the side of the p-type semiconductor layer and decreasing distance to the side of the n-type semiconductor layer in the superlattice semiconductor layer, and the band structure of the superlattice structure can therefore be appropriately modulated. The appropriately modulated band structure of the superlattice structure compensates for the Stark effect in the presence of an internal electric field generated by light received by the superlattice semiconductor layer to allow miniband formation by electronically coupled quantum dots (wave function overlap). In addition, the appropriately modulated band structure allows the energy difference between quantum levels and energy levels of the barrier layers on the side of the n-type region to be decreased gradually in a direction from the p-type semiconductor region toward the n-type semiconductor region to facilitate extraction of carriers generated in the quantum dots.

When the structure is appropriately modulated in terms of a plurality of quantum dot layers to achieve sufficient light absorption by specified bandgaps, sunlight in a wider wavelength range can be sufficiently absorbed, and carriers can be easily extracted from the n-type semiconductor region. Thus, the efficiency of carrier extraction can be enhanced more compared with conventional techniques, and the short-circuit current and the open circuit voltage can be drastically improved to provide a solar cell having higher conversion efficiency.

### BRIEF DESCRIPTION OF THE DRAWINGS

FIG. 1 is a schematic cross sectional view illustrating a configuration of a solar cell according to an embodiment of the present invention;

FIG. 2A is a schematic cross sectional view illustrating a part of a superlattice semiconductor layer in a solar cell according to an embodiment of the present invention;

FIG. 2B is a band diagram of a superlattice structure obtained by simulation in Experiment 1 of the present invention;

FIG. 3 is a diagram showing together wave functions at each energy value of conduction bands of the superlattice structure obtained by the simulation in Experiment 1;

FIG. 4 is a diagram showing wave functions at a minimum energy value of the conduction bands of the superlattice structure obtained by the simulation in Experiment 1;

FIG. 5A is a schematic cross sectional view illustrating a part of a superlattice semiconductor layer in a solar cell according to an embodiment of the present invention;

FIG. 5B is a band diagram of a superlattice structure obtained by simulation in Experiment 2 of the present invention;

FIG. 6 is a diagram showing together wave functions at each energy value of conduction bands of the superlattice structure obtained by the simulation in Experiment 2;

FIG. 7 is a diagram showing wave functions at a minimum energy value of the conduction bands of the superlattice structure obtained by the simulation in Experiment 2;

FIG. 8A is a schematic cross sectional view illustrating a part of a superlattice semiconductor layer in a solar cell according to an embodiment of the present invention;

FIG. 8B is a band diagram of a superlattice structure obtained by simulation in Experiment 3 of the present invention;

FIG. 9 is a diagram showing together wave functions at each energy value of conduction bands of the superlattice structure obtained by the simulation in Experiment 3;

FIG. 10 is a diagram showing wave functions at a minimum energy value of the conduction bands of the superlattice structure obtained by the simulation in Experiment 3;

FIG. 11A is a schematic cross sectional view illustrating a part of a superlattice semiconductor layer in a solar cell according to an embodiment of the present invention;

FIG. 11B is a band diagram of a superlattice structure obtained by simulation in Experiment 4 of the present invention;

FIG. 12 is a diagram showing together wave functions at each energy value of conduction bands of the superlattice structure obtained by the simulation in Experiment 4;

FIG. 13 is a diagram showing wave functions at a minimum energy value of the conduction bands of the superlattice structure obtained by the simulation in Experiment 4;

FIG. 14A is a schematic cross sectional view illustrating a part of a superlattice semiconductor layer in a solar cell according to an embodiment of the present invention;

FIG. 14B is a band diagram of a superlattice structure obtained by simulation in Comparative Experiment;

FIG. 15 is a diagram showing together wave functions at each energy value of conduction bands of the superlattice structure obtained by the simulation in Comparative Experiment; and

FIG. 16 is a diagram showing wave functions at a minimum energy value of the conduction bands of the superlattice structure obtained by the simulation in Comparative Experiment.

### DESCRIPTION OF THE PREFERRED EMBODIMENTS

A solar cell of the present invention comprises: a p-type semiconductor layer; an n-type semiconductor layer; and a superlattice semiconductor layer interposed between the p-type semiconductor layer and the n-type semiconductor layer, wherein the superlattice semiconductor layer has a superlattice structure in which barrier layers and quantum dot layers comprising quantum dots are stacked alternately and repeatedly, and the superlattice semiconductor layer is formed so that the bandgaps of the quantum dots are gradually widened with increasing distance from a side of the p-type semiconductor layer and decreasing distance to a side of the n-type semiconductor layer in the superlattice semiconductor layer.

The superlattice structure means a structure obtained by repeating a stack of a barrier layer of a semiconductor having a bandgap and a well layer (including quantum dot layer) of a semiconductor having a different bandgap, in which the electron wave functions of a well layer and an adjacent well layer greatly interact.

The quantum dots mean semiconductor fine particles having a particle size of 100 nm or less, surrounded with a semiconductor having a bandgap wider than that of the semiconductor forming the quantum dots.

The quantum dot layer means a layer comprising a plurality of quantum dots, being a well layer having a superlattice structure.

The quantum level means a discrete electronic energy level of a quantum dot.

The barrier layer is formed of a semiconductor having a bandgap wider than that of the semiconductor forming the quantum dots and constitutes a superlattice structure.

The miniband means a band formed due to resonant tunneling effect produced between quantum levels of adjacent quantum wells as a result of the interaction between electron wave functions of the adjacent wells in the superlattice structure.

Preferably, in the solar cell of the present invention, the superlattice semiconductor layer is formed so that the sizes of the quantum dots are gradually decreased with increasing distance from the side of the p-type semiconductor layer and decreasing distance to the side of the n-type semiconductor layer in the superlattice semiconductor layer.

Such a configuration produces a quantum size effect of the quantum dots, and the bandgaps of the quantum dots can be gradually widened with increasing distance from the side of the p-type semiconductor layer and decreasing distance to the side of the n-type semiconductor layer in the superlattice semiconductor layer.

Preferably, in the solar cell of the present invention, the quantum dots are formed of a mixed crystal semiconductor, and the superlattice semiconductor layer is formed so that the mixed crystal ratios of the quantum dots included in the quantum dot layers are varied with increasing distance from the side of the p-type semiconductor layer and decreasing distance to the side of the n-type semiconductor layer in the superlattice semiconductor layer.

According to the configuration, the varied mixed crystal ratios of the quantum dots can vary the bandgaps of the quantum dots so that the bandgaps of the quantum dots can be gradually widened with increasing distance from the side of the p-type semiconductor layer and decreasing distance to the side of the n-type semiconductor layer in the superlattice semiconductor layer.

Preferably, in the solar cell of the present invention, the superlattice semiconductor layer is formed so that the energy barrier between the quantum dot layer closest to the n-type semiconductor layer and the barrier layer stacked on the side of the n-type semiconductor layer of the quantum dot layer is 26 meV or less at 300 K of room temperature.

According to the configuration, electrons optically excited to the conduction band of the miniband formed in the superlattice structure can be thermally excited to the energy level at the bottom of the conduction band of the barrier layer closest to the n-type semiconductor layer in the superlattice structure to facilitate extraction of the electrons optically excited to the miniband.

Preferably, in the solar cell of the present invention, the superlattice semiconductor layer is formed so that the difference between a quantum level at the bottom of the conduction bands of the quantum dots included in one of the quantum dot layers and an energy level at the bottom of the conduction band of the barrier layer on the side of the n-type semiconductor layer on the quantum dot layer is gradually decreased with increasing distance from the side of the p-type semiconductor layer and decreasing distance to the side of the n-type semiconductor layer in the superlattice semiconductor layer.

Such a configuration can compensate for the Stark effect in the presence of an internal electric field generated due to light received by a p-i-n junction or a p-n junction to allow miniband formation by electronically coupled quantum dots (wave function overlap).

Preferably, in the solar cell of the present invention, the superlattice semiconductor layer is formed so that a miniband is formed in the superlattice structure in the presence of an internal electric field generated when the p-i-n junction or the p-n junction is subjected to light.

According to the configuration, electronic transition through the miniband can be utilized in addition to normal valence band-to-conduction band transition to allow utilization of light in a wider wavelength range and enhancement of the photoelectric conversion efficiency.

Preferably, in the solar cell of the present invention, the superlattice semiconductor layer is formed so that wave functions of the conduction band of the miniband overlap across the superlattice structure.

According to the configuration, electronic transition through the miniband can be utilized in addition to normal valence band-to-conduction band transition to allow utilization of light in a wider wavelength range and enhancement of the photoelectric conversion efficiency.

Preferably, in the solar cell of the present invention, the superlattice semiconductor layer is formed so that wave functions at a minimum energy value in the conduction band of the miniband overlap across the superlattice structure.

According to the configuration, electronic transition through the miniband can be utilized in addition to normal valence band-to-conduction band transition to allow utilization of light in a wider wavelength range and enhancement of the photoelectric conversion efficiency. In addition, carriers optically excited to the miniband can be transferred through the miniband efficiently.

Preferably, in the solar cell of the present invention, the superlattice semiconductor layer is formed so that only one miniband is formed in the conduction band.

According to the configuration, carriers optically excited to the miniband can be transferred through the miniband efficiently.

Preferably, in the solar cell of the present invention, the p-type semiconductor layer, the n-type semiconductor layer and the superlattice semiconductor layer form a p-n junction (including pn-n junction, pp−n junction, p+pn junction and pnn+junction) or a p-i-n junction.

According to the configuration, the p-i-n junction or the p-n junction can develop an electromotive force when subjected to light.

Preferably, in the solar cell of the present invention, the n-type semiconductor layer is a sunlight incidence plane and the p-type semiconductor layer is an underside. According to the configuration, light in a longer wavelength range of the sunlight can enter deeper toward the bottom so that the sunlight can be absorbed efficiently.

Preferably, in the solar cell of the present invention, the barrier layers or the quantum dot layers are formed of a group III-V compound semiconductor.

According to the configuration, the particle sizes of the quantum dots can be varied easily, and when a mixed crystal of group III-V compound semiconductors is used, the mixed crystal ratios of the quantum dots can be varied easily.

Preferably, in the solar cell of the present invention, the barrier layers are formed of GaAs, and the quantum dot layers are formed of InₓGa₁₋ₓAs (0<x≦1).

According to the configuration, the particle sizes of the quantum dots can be varied easily, and the mixed crystal ratios of the quantum dots can be varied easily.

Preferably, in the solar cell of the present invention, the superlattice semiconductor layer is formed so that the sizes of the quantum dots are gradually decreased by a variation of 1 nm or less with increasing distance from the side of the p-type semiconductor layer and decreasing distance to the side of the n-type semiconductor layer in the superlattice semiconductor layer. More preferably, the superlattice semiconductor layer is formed so that the variation of the sizes of the quantum dots is 0.5 nm or more and 1 nm or less. Being 0.5 nm or more and 1 nm or less, the variation is controllable.

According to the configuration, the bandgaps of the quantum dots can be gradually widened with increasing distance from the side of the p-type semiconductor layer and decreasing distance to the side of the n-type semiconductor layer in the superlattice semiconductor layer.

Preferably, in the solar cell of the present invention, the quantum dots are formed of a mixed crystal semiconductor, and the superlattice semiconductor layer is formed so that the mixed crystal ratios of the quantum dots included in the quantum dot layers are varied by a variation of 0.1 or less with increasing distance from the side of the p-type semiconductor layer and decreasing distance to the side of the n-type semiconductor layer in the superlattice semiconductor layer. Preferably, the superlattice semiconductor layer is formed so that the difference in the mixed crystal ratio between adjacent two quantum dot layers is 0.01 or more and 0.1 or less. Being 0.01 or more and 0.1 or less, the variation is controllable.

According to the configuration, the bandgaps of the quantum dots can be gradually widened with increasing distance from the side of the p-type semiconductor layer and decreasing distance to the side of the n-type semiconductor layer in the superlattice semiconductor layer.

Hereinafter, an embodiment of the present invention will be described with reference to the drawings. Configurations shown in the drawings or the following descriptions are just exemplifications and the scope of the present invention is not limited thereto.

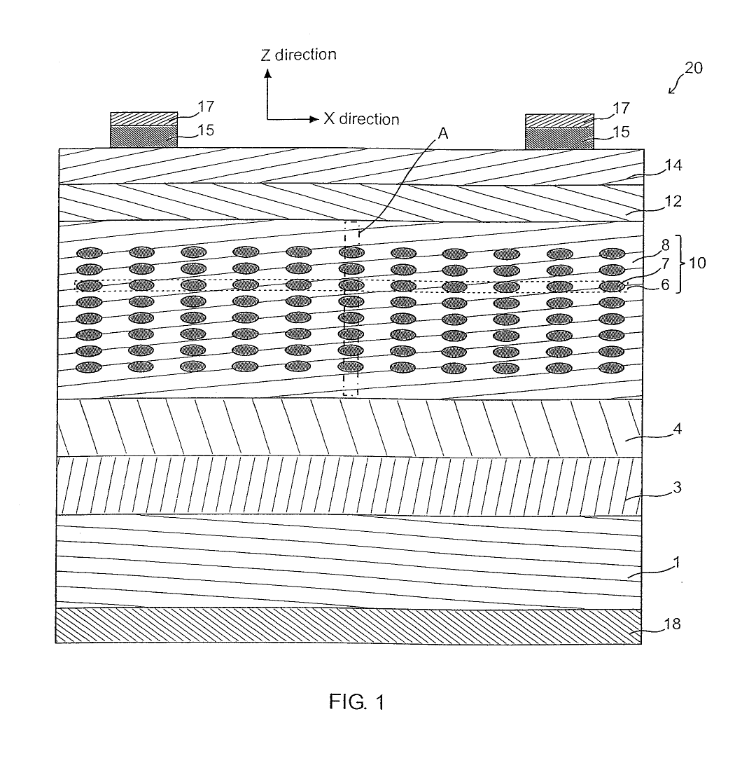

FIG. 1 is a schematic cross sectional view illustrating a configuration of a solar cell according to an embodiment of the present invention.

A solar cell 20 of the present embodiment comprises: a p-type semiconductor layer 1; an n-type semiconductor layer 12; and a superlattice semiconductor layer 10 interposed between the p-type semiconductor layer 1 and the n-type semiconductor layer 12, wherein the superlattice semiconductor layer 10 has a superlattice structure in which barrier layers 8 and quantum dot layers 6 comprising quantum dots 7 are stacked alternately and repeatedly, and the superlattice semiconductor layer 10 is formed so that the bandgaps of the quantum dots 7 are gradually widened with increasing distance from a side of the p-type semiconductor layer and decreasing distance to a side of the n-type semiconductor layer in the superlattice semiconductor layer 10.

The solar cell 20 of the present embodiment may further have a buffer layer 3, a base layer 4, a window layer 14, a contact layer 15, a p-type electrode 18 and an n-type electrode 17.

Hereinafter, the solar cell 20 of the present embodiment will be described.

### 1. P-Type Semiconductor Layer and N-Type Semiconductor Layer

The p-type semiconductor layer 1 is formed of a semiconductor including p-type impurities and can form a p-i-n junction or a p-n junction with an i-type semiconductor layer and the n-type semiconductor layer 12.

The n-type semiconductor layer 12 is formed of a semiconductor including n-type impurities and can form a p-i-n junction or a p-n junction with an i-type semiconductor layer and the p-type semiconductor layer 1.

The p-i-n junction or the p-n junction develops an electromotive force when subjected to light. At the same time, an internal electric field is formed in the superlattice semiconductor layer 10.

As illustrated in FIG. 1, the p-type semiconductor layer 1 or the n-type semiconductor layer 12 may be a substrate, and both of them may be thin films grown by CVD method and so on.

### 2. Superlattice Semiconductor Layer

The superlattice semiconductor layer 10 is interposed between the p-type semiconductor layer 1 and the n-type semiconductor layer 12, and can form a p-i-n junction or a p-n junction. The superlattice semiconductor layer 10 has a superlattice structure in which the barrier layers 8 and the quantum dot layers 6 are stacked alternately and repeatedly. The superlattice semiconductor layer 10 may be an i-type semiconductor layer or a semiconductor layer including p-type impurities or n-type impurities as long as development of an electromotive force is caused by light received.

The materials of the barrier layers 8 and the quantum dot layers 6 constituting the superlattice semiconductor layer 10 are not particularly limited, and examples thereof include a group III-V compound semiconductor. The quantum dot layers 6 are formed of a semiconductor material having a bandgap narrower than the barrier layers 8.

Besides, the materials for forming the superlattice semiconductor layer 10 may be a group IV semiconductor in the periodic table, a compound semiconductor composed of a element of group V and a element of group III, a compound semiconductor composed of a element of group II and a element of group VII or a mixed crystal of these materials. For example, the material of the barrier layers may be GaNAs and the material of the quantum dot layers may be InAs, the material of the barrier layers may be GaP and the material of the quantum dot layers may be InAs or the material of the barrier layers may be GaAs and the material of the quantum dot layers may be GaSb.

The superlattice structure in the superlattice semiconductor layer 10 can be formed by, for example, molecular beam epitaxy (MBE) or metal-organic chemical vapor deposition (MOCVD). However, the present quantum dot formation techniques with these methods have not achieved a density enough to cause electronic coupling between quantum dots in an x-y direction. Here, the x direction refers to a direction parallel to the plane of the layers stacked as illustrated in FIG. 1, and the y direction refers to a direction parallel to the plane of the layers stacked and perpendicular to the x direction. In addition, a z direction refers to a direction perpendicular to the plane of the layers stacked as illustrated in FIG. 1.

With respect to the z direction, on the other hand, the quantum dots 7 can be electronically coupled by decreasing the thickness of each barrier layer 8 to be formed between two quantum dot layers 6. That is, in the case of the superlattice structure including quantum dots, the wave function of the quantum dot structure is equal to the wave function of a quantum well by confinement only in the z direction. On the other hand, the energy value of the quantum dot structure can be assumed to be a sum of an energy value E_{z} of the z direction and energy values (Eₓ, E_{y}) of the x and y directions. The Eₓ and the E_{y} can be determined from energies obtained in a single quantum well in the absence of an electric field.

In a conventional quantum dot solar cell utilizing a miniband, an internal electric field is generated upon light irradiation, and the quantum levels of the quantum dots are split into Stark-ladder states with the energy spacing of eFD (D: superlattice period, F: electric field strength) to reduce carrier mobility. By appropriately modulating the quantum levels of the quantum dots 7 in consideration of this internal electric field, therefore, miniband formation can be sustained. The quantum levels of the quantum dots 7 can be appropriately modulated to sustain miniband formation by forming the superlattice semiconductor layer 10 so that the difference between a quantum level of the quantum dots 7 included in one of the quantum dot layers 6 and an energy level of the conduction band of the barrier layer 8 on the side of the n-type semiconductor layer based on the quantum dots 7 is gradually decreased with increasing distance from the side of the p-type semiconductor layer and decreasing distance to the side of the n-type semiconductor layer. The quantum levels of every quantum dot can be thereby substantially the same to allow formation of a miniband across the superlattice structure, when an internal electric field is generated in the superlattice structure.

Formation of the miniband across the superlattice structure is achieved when all the wave functions of the quantum dots stacked in a stacking direction overlap, not localized. That is, such a miniband is formed when respective quantum dots strongly interact with their adjacent quantum dots to prevent wave function localization.

Examples of the method for modulating the quantum levels of the quantum dots 7 in such a manner include a method in which the particle sizes of the quantum dots 7 included in the quantum dot layers 6 are varied from layer to layer, a method in which the quantum dots 7 are formed of a mixed crystal semiconductor and the mixed crystal ratios of the quantum dots 7 included in the quantum dot layers 6 are varied from layer to layer, and a method in which both the particle sizes and the mixed crystal ratios of the quantum dots 7 included in the quantum dot layers 6 are varied from layer to layer. According to these methods, the superlattice structure can be formed so that the bandgaps of the quantum dots 7 are gradually widened with increasing distance from the side of the p-type semiconductor layer and decreasing distance to the side of the n-type semiconductor layer in the superlattice semiconductor layer 10, and the quantum levels of the quantum dots 7 can be modulated.

The rate of the particle size variation and the rate of the mixed crystal ratio variation are determined so as to sustain the miniband formation in the superlattice structure of the superlattice semiconductor layer even in the presence of an internal electric field. When an internal electric field is uniformly applied to the superlattice semiconductor layer, the rate of the particle size variation and the rate of the mixed crystal ratio variation are determined accordingly. It is assumed that the internal electric field is not applied to the entire superlattice semiconductor layer uniformly, that is, the electric field is not applied around the middle area of the superlattice semiconductor layer when the superlattice semiconductor layer has a sufficient thickness or the superlattice semiconductor layer is doped with an impurity. In this case, the rate of the particle size variation and the rate of the mixed crystal ratio variation are determined in consideration of intensities of the internal electric field to be assumedly applied to each layer so that the quantum levels of every quantum dot 7 will be about the same. In addition, the rate of the particle size variation and the rate of the mixed crystal ratio variation can be determined so that the quantum levels of every quantum dot 7 will be substantially the same energy value throughout the superlattice structure. The wave functions thereby overlap to allow miniband formation. The rate of the particle size variation and the rate of the mixed crystal ratio variation may be constant throughout the superlattice structure or may be varied from quantum dot layers 6 to quantum dot layers 6.

The particle sizes of the quantum dots 7 may be varied by, for example, forming the superlattice semiconductor layer 10 so that the particle sizes of the quantum dots included in the quantum dot layers 6 are gradually decreased layer by layer by a variation of 1 nm or less with increasing distance from the side of the p-type semiconductor layer and decreasing distance to the side of the n-type semiconductor layer in the superlattice semiconductor layer 10. When the particle sizes of the quantum dots 7 included in the quantum dot layers 6 are gradually decreased layer by layer, the quantum levels of the quantum dots 7 can be higher due to a quantum size effect. Thus, the superlattice semiconductor layer 10 can be formed so that the bandgaps of the quantum dots 7 are gradually widened with increasing distance from the side of the p-type semiconductor layer and decreasing distance to the side of the n-type semiconductor layer in the superlattice semiconductor layer 10.

The mixed crystal ratios of the quantum dots 7 may be varied by, for example, forming the quantum dots with a mixed crystal semiconductor such as InₓGa₁₋ₓAs (0<x≦1), and increasing or decreasing the mixed crystal ratios x of the materials for forming the quantum dots included in the quantum dot layers layer by layer by a variation of 0.1 or less with increasing distance from the side of the p-type semiconductor layer and decreasing distance to the side of the n-type semiconductor layer in the superlattice semiconductor layer. By varying the mixed crystal ratios, the bandgaps of the quantum dots 7 included in the quantum dot layers 6 can be gradually widened layer by layer. Thus, the superlattice semiconductor layer 10 can be formed so that the bandgaps of the quantum dots 7 are gradually widened with increasing distance from the side of the p-type semiconductor layer and decreasing distance to the side of the n-type semiconductor layer in the superlattice semiconductor layer 10.

The superlattice semiconductor layer 10 can be formed so that the bandgaps of the quantum dots 7 are gradually widened with increasing distance from the side of the p-type semiconductor layer and decreasing distance to the side of the n-type semiconductor layer in the superlattice semiconductor layer 10 also by concurrently varying the particle sizes of the quantum dots 7 and the mixed crystal ratios of the quantum dots 7. The concurrently varied particle sizes and the mixed crystal ratios of the quantum dots 7 achieve wider modulation.

The bandgaps are modulated so that the wave functions at a minimum energy value overlap across the superlattice semiconductor layer 10, that is, from the side of the p-type semiconductor layer to the side of the n-type semiconductor layer in the superlattice semiconductor layer 10 thereby to form a miniband. As a result, carriers generated in the quantum dot layers 6 move through the miniband and can be easily transferred to the n-type semiconductor layer. When the bandgaps are appropriately modulated, the quantum levels of the quantum dots 7 are gradually increased with decreasing distance to the n-type semiconductor layer 12, and the magnitudes of the energy barriers between the quantum dots 7 and the barrier layers 8 are therefore gradually decreased. The magnitude of the energy barrier between the quantum dot layer 6 closest to the n-type semiconductor layer 12 and the adjacent barrier layer 8 on the side of the n-type semiconductor layer is the smallest of all the magnitudes of the energy barriers between the quantum dot layers 6 and the adjacent barrier layers 8. That is, carriers generated in the quantum dots 7 other than the quantum dots 7 closest to the n-type semiconductor layer 12 are extracted at a magnitude of the energy barrier smaller than the magnitudes of the energy barriers at which the carriers are generated. Thus, extraction of carriers generated in the quantum dot layers 6 can be facilitated.

In the most suitable structure of the superlattice structure, the quantum levels of several tens to several hundreds of quantum dot layers 6 are increased layer by layer in a staircase pattern from the side of the p-type semiconductor layer to the side of the n-type semiconductor layer in the superlattice semiconductor layer 10. That is, in the structure, the quantum dot layers 6 are stacked until the magnitude of the energy barrier in the quantum dots 7 closest to the n-type semiconductor layer 12 is smaller than the thermal energy (hereinafter, referred to as optimum number of layers). Even when the number of quantum dot layers 6 stacked is less than the optimum number of layers, the magnitude of the energy barrier in the quantum dots closest to the n-type semiconductor layer 12 is smaller than the magnitude of the energy barrier at the time of carrier generation in each quantum dot 7 to facilitate excitation.

Further, it is possible to achieve a structure in which the quantum levels are modulated in terms of a plurality of quantum dot layers 6 while forming a miniband with the ground levels of the conduction bands of the quantum dots 7 in the presence of an internal electric field. Such a structure enhances absorption in each bandgap and allows utilization of sunlight in a wider wavelength range to generate a photocurrent when applied to a solar cell.

The above-described structure is also applicable to a quantum well solar cell including quantum well layers allowing miniband formation by such appropriate modulation. However, quantum dots by three-dimensional confinement are more preferable, in which quantum levels are increased more easily, that is, the magnitude of the energy barrier is decreased more easily, and therefore carriers are extracted more easily when applied to a solar cell, compared with quantum wells by only one-dimensional confinement.

### 3. Method for Producing Solar Cell

The quantum dot layers and the quantum well layers can be formed by molecular beam epitaxy (MBE) or metal-organic chemical vapor deposition (MOCVD). Generally, quantum dots can be grown by a mode called Stranski-Krastanov (S-K) growth. In this mode, the mixed crystal ratio of a quantum dot or a quantum well can be adjusted by varying the constituent ratio of materials, and the size of a quantum dot or the width of a quantum well can be adjusted by varying the materials, growth temperature, pressure and/or deposition time.

As the solar cell 20 of the present embodiment, a quantum dot solar cell can be produced by molecular beam epitaxy (MBE), which is better at film thickness control, or metal-organic chemical vapor deposition (MOCVD), for example. The solar cell 20 of the present embodiment can be produced with GaAs as a material of the matrix semiconductors and indium gallium arsenide (InₓGa₁₋ₓAs) whose bandgap can be easily varied in a range of approximately 1.42 eV (GaAs) to 0.36 eV (indium arsenide: InAs) according to the mixed crystal ratio x as a material of the quantum dots, for example. Hereinafter, the method for producing the solar cell 20 will be described in detail.

First, a p-GaAs substrate 1 is washed with an organic cleaning solvent, etched with a sulfuric acid based etching solution, further washed with running water for 10 minutes, and then set in an MOCVD apparatus. On the substrate 1, a p+-GaAs layer having a thickness of 300 nm is formed as the buffer layer 3. The buffer layer 3 is to improve the crystallinity of a light absorption layer to be formed thereon. Subsequently, on the p+-GaAs buffer layer 3, a p-GaAs layer having a thickness of 300 nm and a GaAs layer having a thickness of 1 nm are formed by crystal growth as the base layer 4 and the barrier layer 8, respectively, and then an InAs (x=1) layer is formed as the quantum dot layer 6 by self-organized growth.

A unit of the crystals grown as the barrier layer 8 and the quantum dot layer 6 can be repeated while gradually decreasing the mixed crystal ratios x of the InₓGa₁₋ₓAs starting from 1 at the quantum dots closest to the p-type semiconductor layer 1 toward the quantum dots closest to the n-type semiconductor layer 12. Alternatively, the unit can be repeated while gradually varying the sizes of the quantum dots 7 at a certain constant mixed crystal ratio x. Alternatively, both the mixed crystal ratios x and the sizes of the quantum dots may be varied.

After the crystal growth of the quantum dot layers 6, a GaAs cap layer (not shown) having a thickness of approximately 4 nm is grown to regain the flatness of a surface of the crystal to complete the superlattice semiconductor layer 10. Subsequently, on the cap layer, an n-GaAs layer having a thickness of 250 nm is formed as the n-type semiconductor layer 12 by crystal growth to form a p-i-n structure, and then an n-Al_{0.75}Ga_{0.25}As layer having a thickness of 50 nm is formed as the window layer 14. Then, a pt-GaAs layer having a thickness of 100 nm is formed as the contact layer 15 by crystal growth. Next, the layers stacked are taken out of the MOCVD apparatus, and then the p-type electrode 18 is formed on the entire bottom surface of the substrate. Then, on the contact layer 15, an interdigitated electrode is formed by photo-lithography and lift-off process, and then the contact layer 15 is selectively etched with the interdigitated electrode as a mask to form the n-type electrode 17. Thus, the quantum dot solar cell 20 can be formed.

The temperature for processing the substrate may be 520° C. only for the formation of the superlattice semiconductor layer 10 including the quantum dot layers 6 in order to prevent re-desorption of In and may be 590° C. for the crystal growth of the other layers, for example.

Si may be used as an n-type dopant and Be may be used as a p-type dopant, for example. The electrode may be formed of Au by vacuum deposition by resistance heat deposition, for example.

The embodiment described herein is merely an example, and the constituents such as the substrate, the buffer layer, the quantum dots, the dopants and the electrodes to use for the solar cell of the present invention; and the cleaning agent, the temperature for processing the substrate, the apparatus to employ in each production process are not limited to those mentioned in the example.

### Simulation Experiments

Simulation experiments in which the Schroedinger equation was solved by using MATLAB software were carried out.

### [Experiment 1]

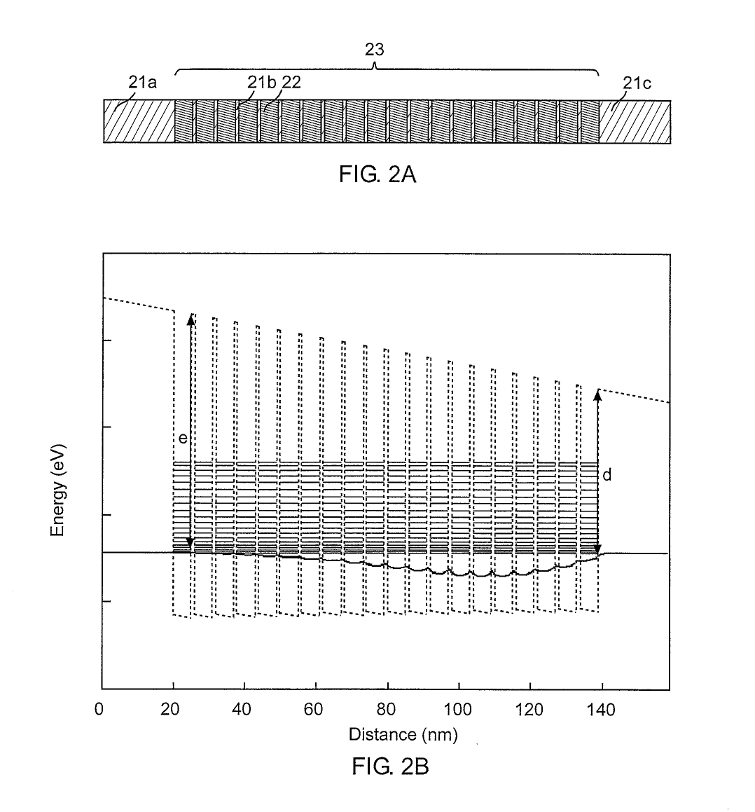

Experiment 1 is directed to an exemplary quantum dot solar cell in which the mixed crystal ratios of the quantum dots included in the quantum dot layers were varied from layer to layer to modulate the quantum levels. Hereinafter, Experiment 1 will be described in detail with reference to FIGS. 2 to 4.

FIG. 2B is a band diagram of a superlattice structure in which the mixed crystal ratios of the quantum dots according to the calculation in Experiment 1 were varied to modulate the quantum levels. FIG. 2A is a schematic cross sectional view illustrating a part of the superlattice semiconductor layer 10. FIG. 2A corresponds to an area A enclosed by an alternate long and short dash line in FIG. 1. The horizontal axis of FIG. 2B represents the distance in the stacking direction (z direction in FIG. 1) based on the interface between the superlattice semiconductor layer and the p-type semiconductor layer whose distance is 0, and coincides with the lateral direction of FIG. 2A in terms of the positional relationship. Meanwhile, the vertical axis of FIG. 2B represents the energy.

In Experiment 1, there was carried out a simulation in which gallium arsenide (GaAs) was used for matrix semiconductor materials for forming barrier layers 21a to 21c, an p-type semiconductor layer and a p-type semiconductor layer, indium gallium arsenide (InₓGa₁₋ₓAs) was used for a material of quantum dots for forming quantum dot layers 22, and energy bands when an internal electric field of 15 kV/cm was applied to a superlattice structure obtained by stacking 20 quantum dot layers 22 were calculated. Since the impurity densities of the n-type and p-type matrix semiconductors were sufficiently larger than that of a superlattice semiconductor layer 23, it was assumed that the internal electric field was applied to the superlattice semiconductor layer 23 uniformly.

The internal electric field of 15 kV/cm is equal to an internal electric field of 0.6 V applied to the superlattice semiconductor layer 23 having a thickness of 400 nm, for example. Likewise, the internal electric field of 15 kV/cm is equal to an internal electric field of 0.54 V applied to the superlattice semiconductor layer 23 having a thickness of 360 nm and to an internal electric field of 0.45 V applied to the superlattice semiconductor layer 23 having a thickness of 300 nm.

The mixed crystal ratios x in the quantum dot layers 22 were varied so that the quantum levels of the quantum dot layers 22 are gradually increased with decreasing distance to the n-type semiconductor layer. In Experiment 1, each barrier layer 21b interposed between two quantum dot layers 22 had a thickness of 1 nm, the quantum dots each had a size of 20 nm in length and breadth (xy directions) and 5 nm in height (z direction), and the barrier layer 21c on the side of the n-type semiconductor layer of the quantum dot layer 22 closest to the n-type semiconductor layer and the barrier layer 21a on the side of the p-type semiconductor layer of the quantum dot layer 22 closest to the p-type semiconductor layer each had a sufficient thickness of 20 nm. The magnitude of the barrier between the gallium arsenide and the indium arsenide was 0.697 eV.

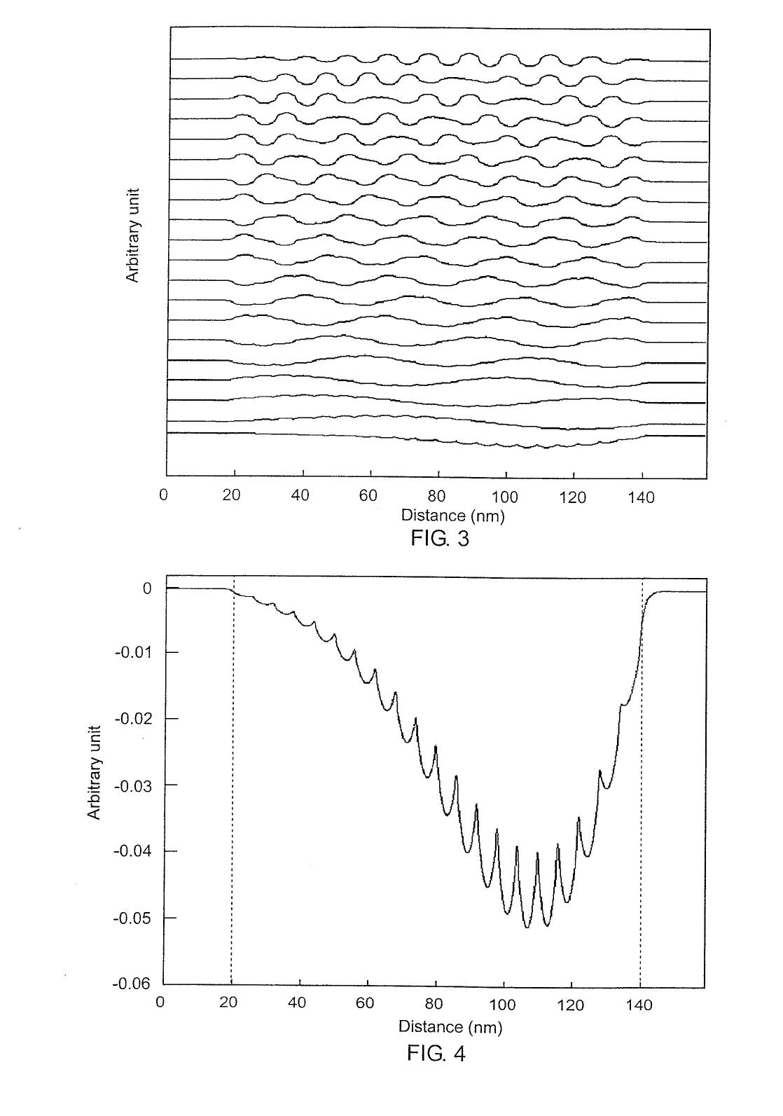

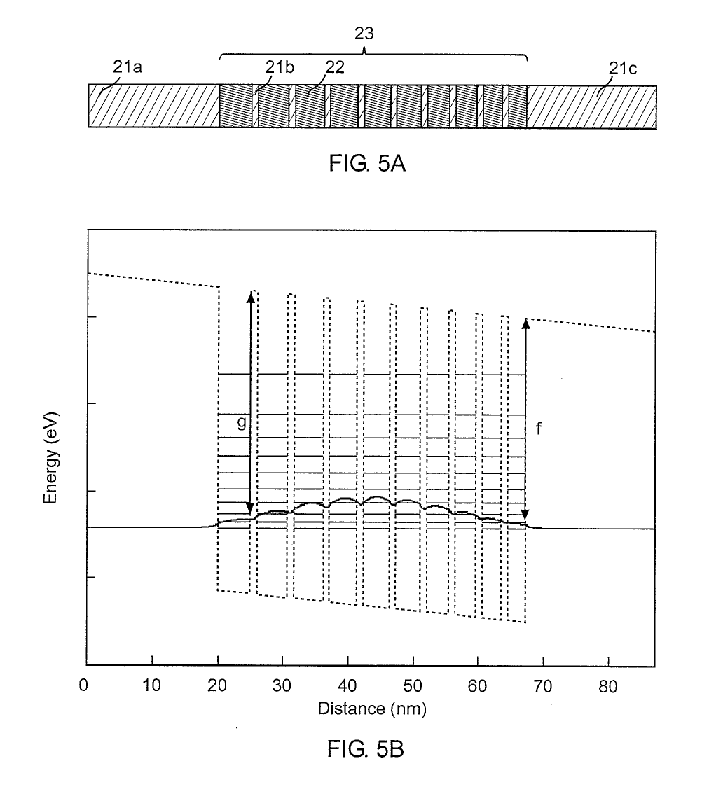

The valence bands were considered one band because the effective mass of the hole was large, for which FIG. 2B shows only some energy values possible at the side of the conduction band and wave functions at the minimum energy by solid lines. The dotted line represents energy levels at the bottoms of the conduction bands of the barrier layers 21a to 21c and energy levels on the assumption that the quantum dots have energy levels at the bottoms of the conduction bands in bulk state. FIG. 3 is a diagram showing together wave functions at each energy value possible at the side of the conduction band. FIG. 4 is an enlarged view showing wave functions at the minimum energy value of the conduction band. FIGS. 5 to 7, FIGS. 8 to 10, FIGS. 11 to 13, and FIGS. 14 to 16 show results of respective experiments and correspond to FIGS. 2 to 4.

FIG. 4 indicates that all the wave functions at the minimum energy overlap across the superlattice structure (ranging from the distance of 20 nm to the distance of 140 nm on the horizontal axis of FIG. 4) to form a miniband showing high carrier mobility.

Further, FIG. 2B indicates that the quantum levels of the quantum dot layers 22 are gradually increased with decreasing distance to the n-type semiconductor layer and that the magnitudes of the energy barriers between the respective quantum dot layers 22 and the adjacent barrier layers 21b are gradually decreased with decreasing distance to the n-type semiconductor layer.

In the band diagram of FIG. 2, the differences between the minimum quantum levels of the quantum dot layers 22 and the energy levels of the adjacent barrier layers 21b on the side of the n-type semiconductor are decreased gradually from 547 meV between the quantum dot layer 22 closest to the p-type semiconductor layer and the barrier layer 21a (difference e shown in FIG. 2B) to 376 meV between the quantum dot layer 22 closest to the n-type semiconductor layer and the barrier layer 21c (difference d shown in FIG. 2B). That is to say, the magnitudes of the energy barriers are gradually decreased while sustaining miniband formation to facilitate extraction of generated carriers from the n-type semiconductor layer.

### [Experiment 2]

Experiment 2 is directed to an exemplary quantum dot solar cell in which the sizes of the quantum dots in the quantum dot layers were varied from layer to layer to modulate the quantum levels. Hereinafter, Experiment 2 will be described in detail with reference to FIGS. 5 to 7. FIG. 5B is a band diagram of a case where gallium arsenide (GaAs) was used for the matrix semiconductor material, indium arsenide (InAs) was used for the quantum dot material, and an internal electric field of 15 kV/cm was applied to a quantum dot structure obtained by stacking 10 quantum dot layers. FIG. 5A is a schematic cross sectional view illustrating a part of the superlattice semiconductor layer 10. Since the impurity densities of the n-type and p-type matrix semiconductors were sufficiently larger than that of the i-type semiconductor layer, it was assumed that the internal electric field was applied to the i-type semiconductor layer uniformly as in the case of Experiment 1.

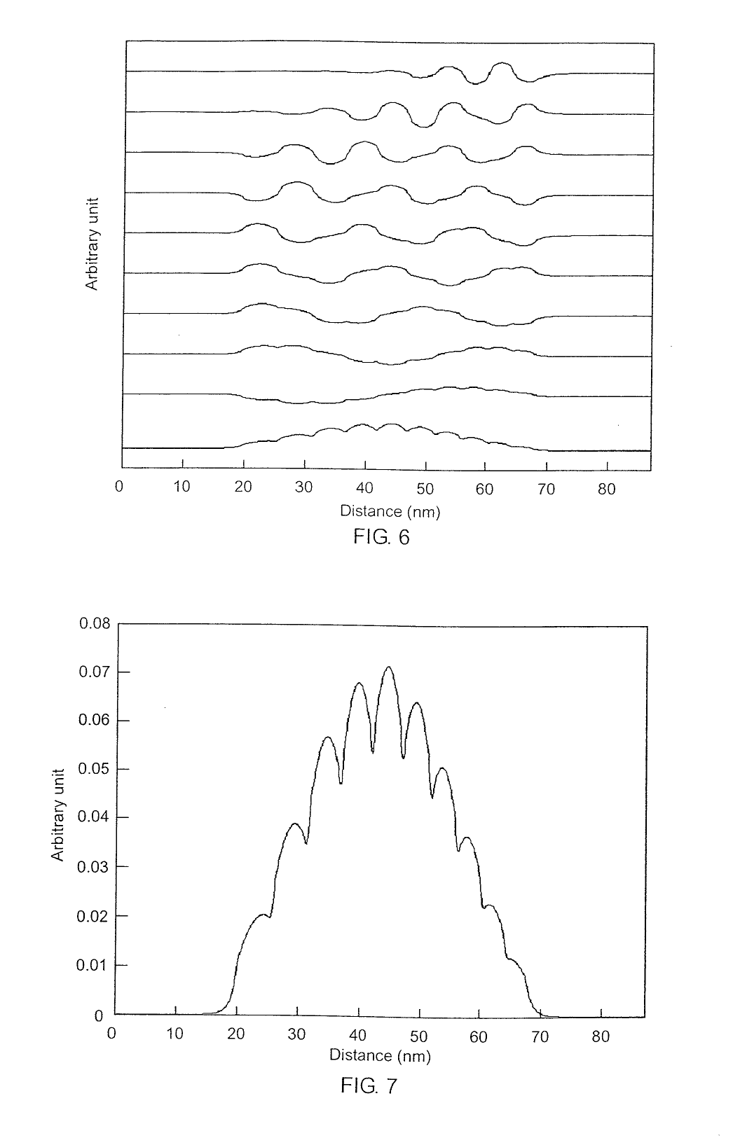

FIG. 5B is a band diagram of a superlattice structure in which the quantum dot sizes were varied from quantum dot layer 22 to quantum dot layer 22 to modulate the quantum levels. In FIG. 5B, the quantum levels are gradually increased with decreasing distance to the n-type semiconductor layer. The valence bands were considered one band because the effective mass of the hole was large, for which the band diagram shows only some energy values possible at the side of the conduction band and wave functions at the minimum energy. The barrier layers 21b each had a thickness of 1 nm, the quantum dots each had a size of 20 nm in length and breadth (xy directions) and 5 nm in height (z direction), and the barrier layer 21c on the side of the n-type semiconductor layer of the quantum dot layer 22 closest to the n-type semiconductor layer and the barrier layer 21a on the side of the p-type semiconductor layer of the quantum dot layer 22 closest to the p-type semiconductor layer each had a sufficient thickness of 20 nm. In FIG. 5B, the height (z direction) of the quantum dot layers 22 is decreased gradually from 5 nm. The magnitude of the barrier between the gallium arsenide and the indium arsenide was 0.697 eV. FIG. 6 shows together wave functions at respective energy values. FIG. 7 is an enlarged view showing wave functions at the minimum energy.

FIG. 7 indicates that all the wave functions at the minimum energy overlap across the superlattice structure (ranging from the distance of 20 nm to the distance of 70 nm on the horizontal axis of FIG. 7) to form a miniband showing high carrier mobility.

Further, FIG. 5B indicates that the quantum levels of the quantum dot layers 22 are gradually increased with decreasing distance to the n-type semiconductor layer and that the magnitudes of the energy barriers between the respective quantum dot layers 22 and the adjacent barrier layers 21b are gradually decreased with decreasing distance to the n-type semiconductor layer.

In the band diagram of FIG. 5, the differences between the quantum levels of the quantum dot layers 22 and the energy levels of the adjacent barrier layers 21b on the side of the n-type semiconductor are decreased gradually from 547 meV between the quantum dot layer 22 closest to the p-type semiconductor layer and the barrier layer 21a (difference g shown in FIGS. 5) to 483 meV between the quantum dot layer 22 closest to the n-type semiconductor layer and the barrier layer 21c (difference f shown in FIG. 5) when the quantum dot sizes are gradually decreased with increasing distance from the interface between the i-type semiconductor layer and the p-type semiconductor layer and decreasing distance to the side of the n-type semiconductor layer. That is to say, the magnitudes of the energy barriers are gradually decreased while sustaining miniband formation to facilitate extraction of generated carriers from the n-type semiconductor region.

### [Experiment 3]

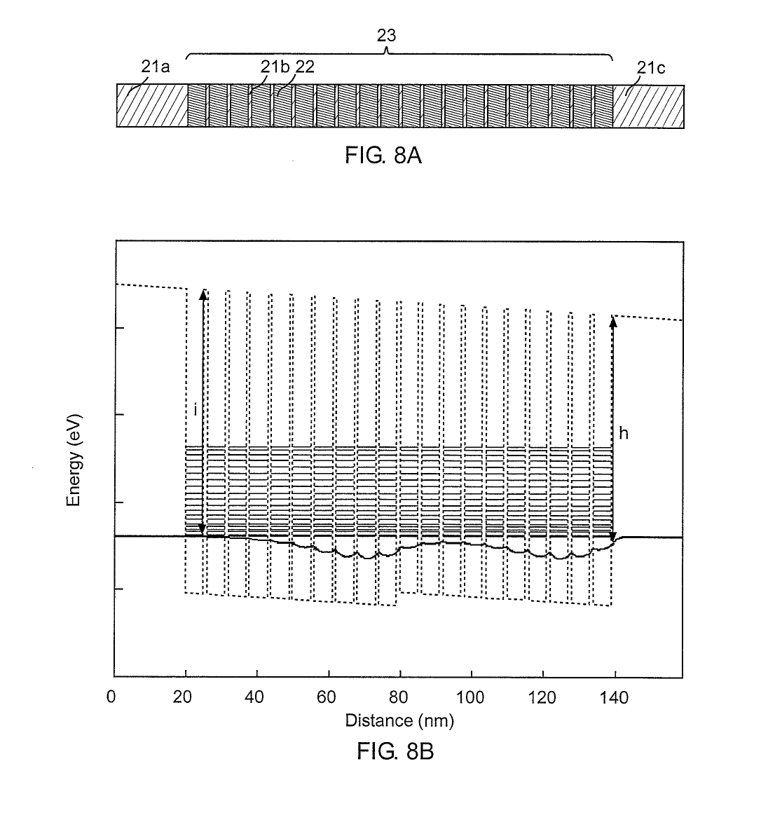

Experiment 3 is directed to an exemplary quantum dot solar cell in which the mixed crystal ratios were varied in terms of a plurality of quantum dot layers to modulate the quantum levels. Hereinafter, Experiment 3 will be described in detail with reference to FIGS. 8 to 10.

FIG. 8B is a band diagram of a case where an internal electric field of 5 kV/cm was applied to a superlattice structure obtained by stacking 20 quantum dot layers having quantum levels modulated by varying the mixed crystal ratios in terms of 10 quantum dot layers. FIG. 8A is a schematic cross sectional view illustrating a part of the superlattice semiconductor layer 10. The internal electric field of 5 kV/cm is equal to an internal electric field of 0.6 V applied to the i-type semiconductor layer having a thickness of 1200 nm. Likewise, the internal electric field of 5 kV/cm is equal to an internal electric field of 0.5 V applied to the i-type semiconductor layer having a thickness of 1000 nm and to an internal electric field of 0.4 V applied to the i-type semiconductor layer having a thickness of 800 nm.

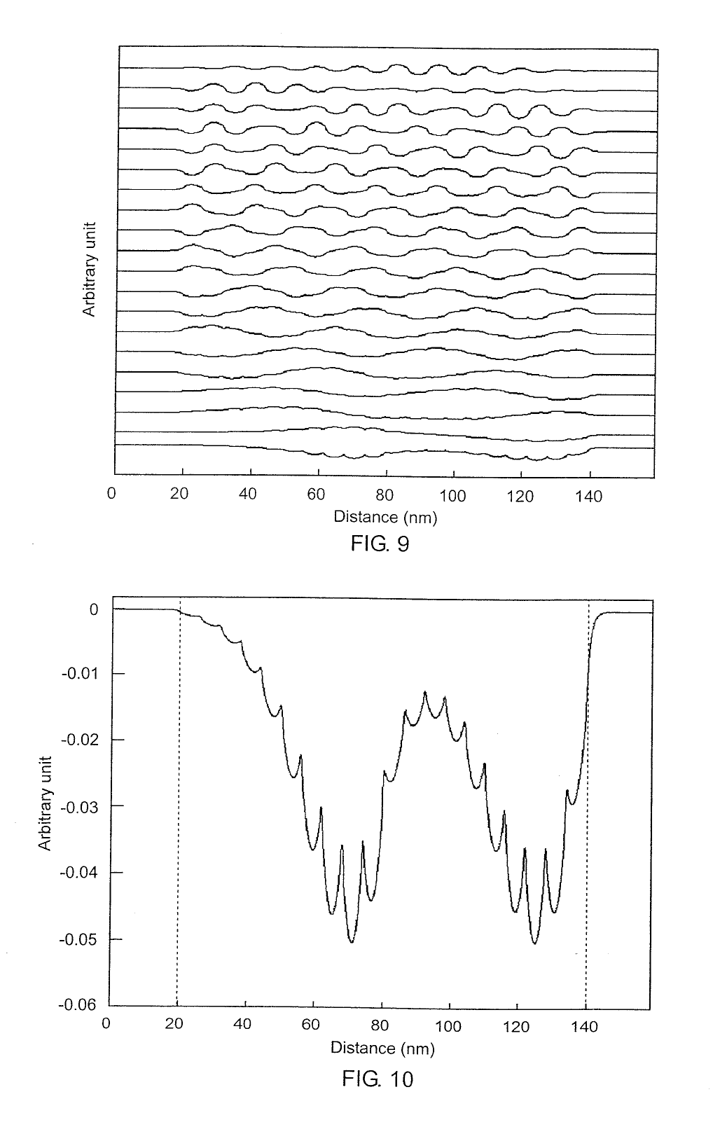

As in the case of the other experiments, gallium arsenide (GaAs) was used for the matrix semiconductor materials, indium gallium arsenide (InₓGa₁₋ₓAs) was used for the quantum dot material, the barrier layers each had a thickness of 1 nm, the quantum dots each had a size of 20 nm in length and breadth (xy directions) and 5 nm in height (z direction), and the barrier layer 21a and the barrier layer 21c on the quantum dot layers at opposite ends each had a sufficient thickness of 20 nm. The magnitude of the barrier between the gallium arsenide and the indium arsenide was 0.697 eV. FIG. 9 shows together wave functions at respective energy values. FIG. 10 is an enlarged view showing wave functions at the minimum energy value. FIG. 10 indicates that all the wave functions at the minimum energy overlap across the superlattice structure (ranging from the distance of 20 nm to the distance of 140 nm on the horizontal axis of FIG. 10). In addition, the differences between the minimum quantum levels of the quantum dot layers 22 and the energy levels of the adjacent barrier layers 21b on the side of the n-type semiconductor are decreased gradually from 564 meV between the quantum dot layer 22 closest to the p-type semiconductor layer and the barrier layer 21a (difference i shown in FIG. 8B) to 507 meV between the quantum dot layer 22 closest to the n-type semiconductor layer and the barrier layer 21c (difference h shown in FIG. 8B). That is to say, the magnitudes of the energy barriers are gradually decreased while sustaining miniband formation to facilitate extraction of generated carriers from the n-type semiconductor region.

By varying the mixed crystal ratios in terms of a plurality of quantum dot layers, sufficient light absorption is achieved by each bandgap of the quantum dot layers.

That is, the quantum dot solar cell in which the materials are modulated in terms of a plurality of quantum dot layers is capable of sufficient absorption of light according to each bandgap of the quantum dot layers to result in absorption of light in a wider wavelength range and easy carrier extraction from the n-type semiconductor region.

### [Experiment 4]

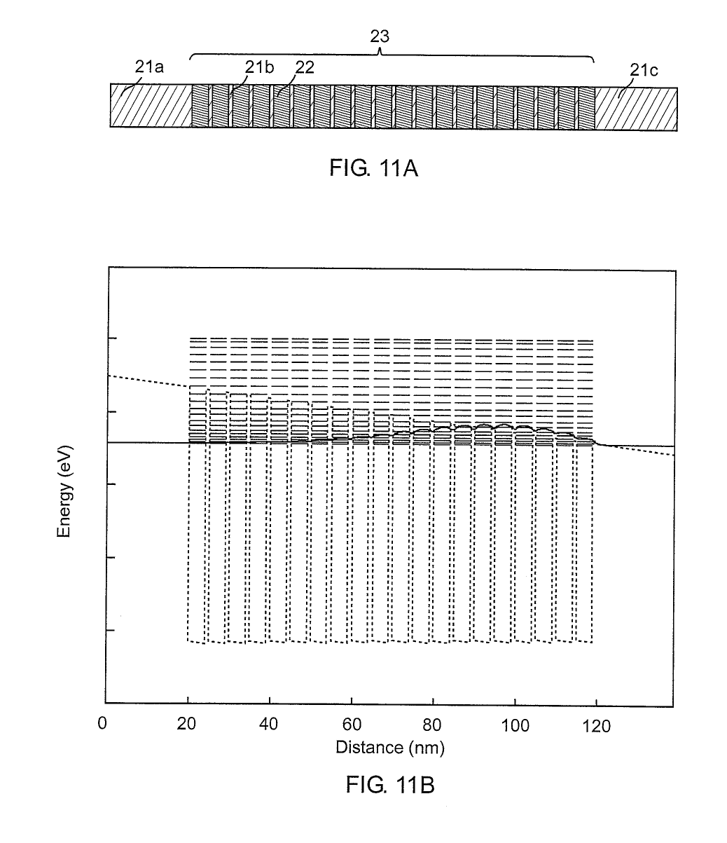

Experiment 4 is directed to an exemplary quantum dot solar cell in which the mixed crystal ratios were varied from quantum dot layer to quantum dot layer so that the quantum levels were modulated and the energy barrier between the quantum dot layer closest to the n-type semiconductor layer and the barrier layer on the side of the n-type semiconductor layer of the quantum dot layer was limited to 26 meV or less. Hereinafter, Experiment 4 will be described in detail with reference to FIGS. 11 to 13.

FIG. 11B is a band diagram of a case where gallium arsenide (GaAs) was used for the matrix semiconductor materials, indium gallium arsenide (InₓGa₁₋ₓAs) was used for the quantum dot material, and an internal electric field of 15 kV/cm was applied to a quantum dot structure obtained by stacking 20 quantum dot layers. FIG. 11A is a schematic cross sectional view illustrating a part of the superlattice semiconductor layer 10. Since the impurity densities of the n-type and p-type matrix semiconductors were sufficiently larger than that of the superlattice semiconductor layer, it was assumed that the internal electric field was applied to the superlattice semiconductor layer uniformly.

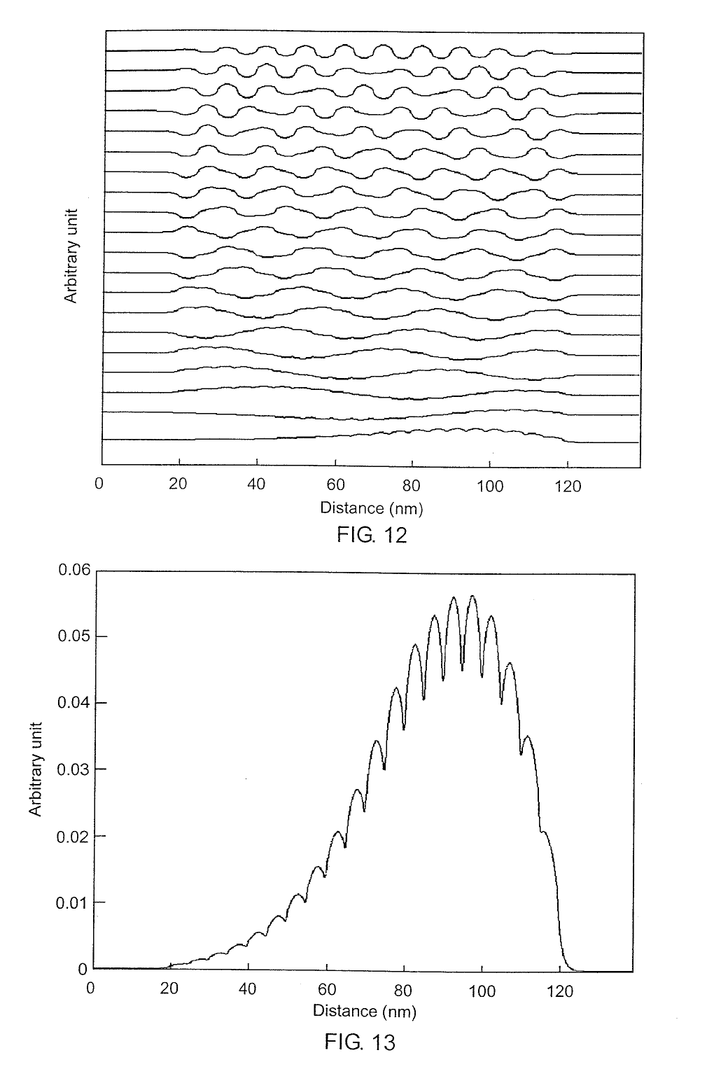

FIG. 11B is a band diagram of the quantum dot structure in which the mixed crystal ratios were varied from quantum dot layer 22 to quantum dot layer 22 to modulate the quantum levels. As shown in FIG. 11B, the quantum levels are gradually increased with decreasing distance to the n-type semiconductor layer. The valence bands were considered one band because the effective mass of the hole was large, for which FIG. 11B shows only some energy values possible at the side of the conduction band and wave functions at the minimum energy. The barrier layers each had a thickness of 1 nm, the quantum dots each had a size of 4 nm in length and breadth (xy directions) and 4 nm in height (z direction), and the barrier layer 21a and the barrier layer 21c on the quantum dot layers at opposite ends each had a sufficient thickness of 20 nm. The magnitude of the barrier between the gallium arsenide and the indium arsenide was 0.697 eV. FIG. 12 shows together wave functions at respective energy values. FIG. 13 is an enlarged view showing wave functions at the minimum energy value.

FIG. 13 indicates that all the wave functions at the minimum energy overlap across the superlattice structure (ranging from the distance of 20 nm to the distance of 120 nm on the horizontal axis of FIG. 13) to form a miniband showing high carrier mobility.

Further, FIG. 11B indicates that the quantum levels of the quantum dot layers 22 are gradually increased with decreasing distance to the n-type semiconductor layer and that the magnitudes of the energy barriers between the respective quantum dot layers 22 and the adjacent barrier layers 21b are gradually decreased with decreasing distance to the n-type semiconductor layer.

In the band diagram of FIG. 11, the differences between the minimum quantum levels of the quantum dot layers 22 and the energy levels of the adjacent barrier layers 21b on the side of the n-type semiconductor are decreased gradually from 147 meV between the quantum dot layer 22 closest to the p-type semiconductor layer and the barrier layer 21a to 5 meV between the quantum dot layer 22 closest to the n-type semiconductor layer and the barrier layer 21c. That is to say, the magnitudes of the energy barriers are gradually decreased while sustaining miniband formation and the energy barrier between the quantum dot layer closest to the n-type semiconductor layer and the barrier layer on the side of the n-type semiconductor layer of the quantum dot layer is limited to 26 meV, which is equal to the thermal energy at 300 K of room temperature, or less to facilitate extraction of generated carriers from the n-type semiconductor region.

The variation of the sizes of the quantum dots was 1 nm or less and the variation of the mixed crystal ratios of the quantum dots was 0.1 or less for the modulation of the quantum levels in all Experiments 1 to 4.

### [Comparative Experiment]

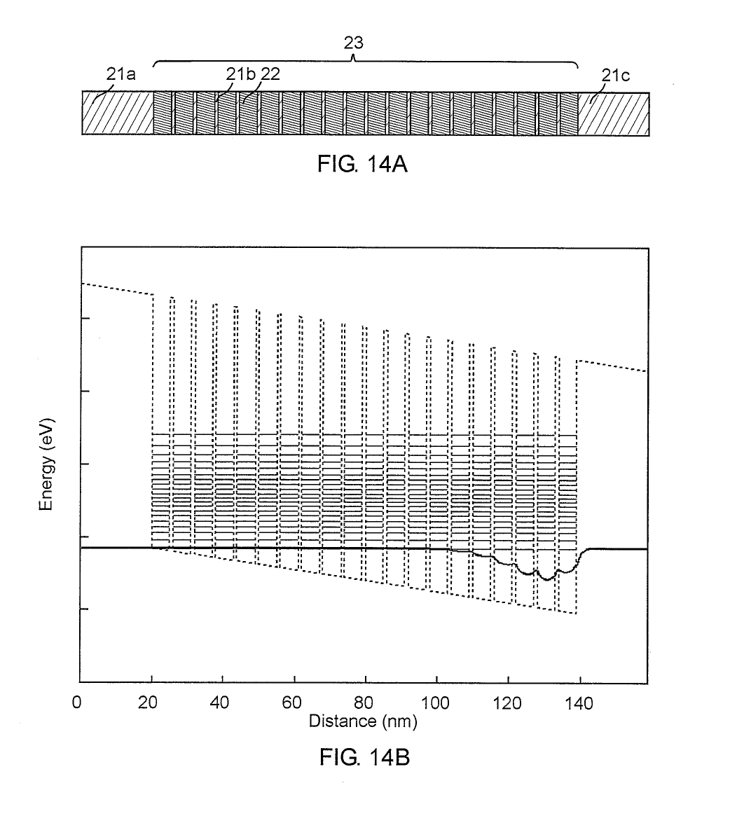

Comparative Experiment is directed to an exemplary quantum dot solar cell in which neither the mixed crystal ratios nor the quantum dot sizes were varied, that is, the quantum levels were not modulated. Hereinafter, Comparative Experiment will be described in detail with reference to FIGS. 14 to 16.

FIG. 14B is a band diagram of a case where the materials were not modulated and the quantum dot sizes were not varied so that the quantum levels were not modulated, and an internal electric field of 15 kV/cm was applied to a superlattice structure obtained by stacking 20 quantum dot layers. FIG. 14A is a schematic cross sectional view illustrating a part of the superlattice semiconductor layer 10. As in the case of the other experiments, gallium arsenide (GaAs) was used for the matrix semiconductor materials, indium arsenide (InAs) was used for the quantum dot material, the barrier layers each had a thickness of 1 nm, the quantum dots each had a size of 20 nm in length and breadth (xy directions) and 5 nm in height (z direction), and the barrier layer 21a and the barrier layer 21c on the quantum dot layers at opposite ends each had a sufficient thickness of 20 nm. The magnitude of the barrier between the gallium arsenide and the indium arsenide was 0.697 eV.

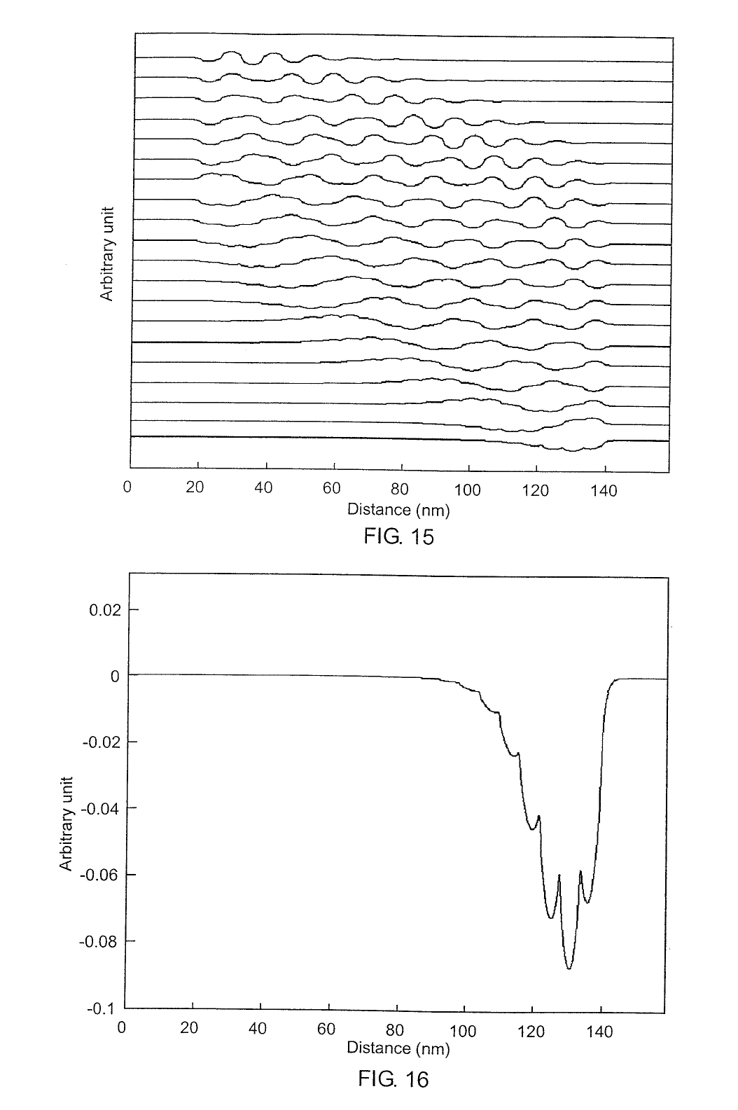

FIG. 15 shows together wave functions at respective energy values. FIG. 16 is an enlarged view showing wave functions at the minimum energy value. FIG. 16 indicates that not all the wave functions at the minimum energy overlap across the superlattice semiconductor layer 23, unlike the case of Experiment 1 where the quantum levels were modulated. That is, the wave functions at the minimum energy extend only in a range of the distances on the horizontal axis of approximately 90 nm to 140 nm, failing to extend across the superlattice structure (ranging from the distance of 20 nm to the distance of 140 nm on the horizontal axis of FIG. 16), and the wave functions are localized in terms of the entire superlattice structure. It is therefore assumed that this quantum dot solar cell is inefficient, showing significantly reduced carrier mobility compared with the case where the quantum levels were modulated.

What is claimed is:

1. A solar cell comprising a p-type semiconductor layer, an n-type semiconductor layer, and a superlattice semiconductor layer interposed between the p-type semiconductor layer and the n-type semiconductor layer, wherein
the superlattice semiconductor layer has a superlattice structure in which barrier layers and quantum dot layers comprising quantum dots are stacked alternately and repeatedly, and is formed so that the bandgaps of the quantum dots are gradually widened with increasing distance from a side of the p-type semiconductor layer and decreasing distance to a side of the n-type semiconductor layer.

2. The solar cell according to claim 1, wherein the superlattice semiconductor layer is formed so that the sizes of the quantum dots are gradually decreased with increasing distance from the side of the p-type semiconductor layer and decreasing distance to the side of the n-type semiconductor layer.

3. The solar cell according to claim 1, wherein the quantum dots are formed of a mixed crystal semiconductor, and the superlattice semiconductor layer is formed so that the mixed crystal ratios of the quantum dots included in the quantum dot layers are varied with increasing distance from the side of the p-type semiconductor layer and decreasing distance to the side of the n-type semiconductor layer.

4. The solar cell according to claim 1, wherein the superlattice semiconductor layer is formed so that the difference between a quantum level at the bottom of the conduction bands of the quantum dots included in one of the quantum dot layers and an energy level at the bottom of the conduction band of the barrier layer on the side of the n-type semiconductor layer on the quantum dot layer is gradually decreased with increasing distance from the side of the p-type semiconductor layer and decreasing distance to the side of the n-type semiconductor layer.

5. The solar cell according to claim 1, wherein the superlattice semiconductor layer is formed so that the energy barrier between the quantum dot layer closest to the n-type semiconductor layer and the barrier layer stacked on the side of the n-type semiconductor layer of the quantum dot layer is 26 meV or less at 300 K of room temperature.

6. The solar cell according to claim 1, wherein the superlattice semiconductor layer is formed so that a miniband is formed in the superlattice structure in the presence of an internal electric field generated when the superlattice semiconductor layer is subjected to light.

7. The solar cell according to claim 6, wherein the superlattice semiconductor layer is formed so that wave functions of the conduction band of the miniband overlap across the superlattice structure.

8. The solar cell according to claim 6, wherein the superlattice semiconductor layer is formed so that wave functions at a minimum energy value in the conduction band of the miniband overlap across the superlattice structure.

9. The solar cell according to claim 6, wherein the superlattice semiconductor layer is formed so that only one miniband is formed in the conduction band.

10. The solar cell according to claim 1, wherein the p-type semiconductor layer, the n-type semiconductor layer and the superlattice semiconductor layer form a p-n junction or a p-i-n junction.

11. The solar cell according to claim 1, wherein the p-type semiconductor layer, the n-type semiconductor layer and the superlattice semiconductor layer are arranged so that the n-type semiconductor layer is placed on an incidence-plane side.

12. The solar cell according to claim 1, wherein the barrier layers or the quantum dot layers are formed of a group III-V compound semiconductor.

13. The solar cell according to claim 1, wherein the barrier layers are formed of GaAs, and the quantum dot layers are formed of InₓGa₁₋ₓAs (0<x≦1).

14. The solar cell according to claim 1, wherein the superlattice semiconductor layer is formed so that the sizes of the quantum dots are gradually decreased by a variation of 1 nm or less with increasing distance from the side of the p-type semiconductor layer and decreasing distance to the side of the n-type semiconductor layer.

15. The solar cell according to claim 1, wherein the quantum dots are formed of a mixed crystal semiconductor, and the superlattice semiconductor layer is formed so that the mixed crystal ratios of the quantum dots included in the quantum dot layers are varied by a variation of 0.1 or less with increasing distance from the side of the p-type semiconductor layer and decreasing distance to the side of the n-type semiconductor layer.
